(19) United States
(12) Patent Application Publication
(10) Pub. No.: US 2015/0014682 A1
(43) Pub. Date: Jan. 15, 2015

(54) SEMICONDUCTOR DEVICE

(71) Applicant: Renesas Electronics Corporation, Kawasaki-shi (JP)

(72) Inventors: Nobuyuki Ikarashi, Kanagawa (JP); Kishou Kaneko, Kanagawa (JP); Kiyoshi Takeuchi, Kanagawa (JP)

(21) Appl. No.: 14/328,430

(22) Filed: Jul. 10, 2014

(30) Foreign Application Priority Data
Jul. 11, 2013 (JP) 2013-145252

(51) Int. Cl. H01L 29/786

(52) U.S. Cl. CPC H01L 29/7869
USPC 257/43

(57) ABSTRACT

Disclosed is a semiconductor device in which the quality of an oxide semiconductor film is stabilized, while the property that an oxide semiconductor has high mobility is being utilized. The semiconductor device includes an oxide semiconductor layer and an electrode. The electrode is coupled to one surface of the oxide semiconductor layer. A portion of the oxide semiconductor layer, spanning from the one surface to a depth of t, becomes an ordered layer. The ordered layer is an area including a plurality of ordered regions in each of which the arrangement of atoms is compliant with a specific rule. The maximum width of the ordered region in a section in a direction perpendicular to the one surface is 2 nm or less.

### CROSS-REFERENCE TO RELATED APPLICATIONS

The disclosure of Japanese Patent Application No. 2013-145252 filed on Jul. 11, 2013 including the specification, drawings and abstract is incorporated herein by reference in its entirety.

### BACKGROUND

The present invention relates to a semiconductor device, and in particular, to a technique applicable to a semiconductor device including, for example, an oxide semiconductor.

In recent years, techniques have been developed, in each of which an element is formed by using an oxide semiconductor, such as InGaZnO₄. For example, in “A Polycrystalline Oxide TFT Driven Active Matrix-OLED Display”, Yasuhiro Terai and seven others, ITE (Institute of Image Information and Television Engineers) Journal, J 339-J 345, Vol. 66, No. 10 (2012), it is shown that the mobility of a TFT using polycrystalline InGaO is higher than that of a TFT using amorphous InGaZnO₄.

Also, in Japanese Unexamined Patent Publication No. 2010-141230, it is described that a transistor is formed by using an oxide semiconductor layer formed of InGaZnO₄, ZnO, or the like, which has been provided in an interconnection layer.

### SUMMARY

In recent years, research toward the practical use of transistors using polycrystalline InGaZnO₄ has not advanced, while putting transistors using amorphous InGaZnO₄ into practical use has advanced. It is because the quality of a polycrystalline InGaZnO₄ film is not stabilized. However, the mobility of a carrier in a semiconductor becomes higher as the crystallinity becomes higher. Accordingly, the property that an oxide semiconductor has high mobility is not sufficiently utilized in amorphous InGaZnO₄. The present inventors have investigated how to stabilize the quality of an oxide semiconductor film while the property that an oxide semiconductor has high mobility is being utilized. Other problems and new characteristics will become clear from the description and accompanying drawings of the present specification.

According to one embodiment, a semiconductor device includes an oxide semiconductor layer and an electrode coupled to the oxide semiconductor layer. The oxide semiconductor layer includes a plurality of ordered regions in each of which the arrangement of atoms is compliant with a specific rule, in an area spanning at least from a surface (one surface), to which the electrode is coupled, to a depth of 2 nm. The maximum width of the ordered region in a section in a direction perpendicular to the one surface is 2 nm or less.

According to the one embodiment, the quality of an oxide semiconductor film can be stabilized, while the property that an oxide semiconductor has high mobility is being utilized.

### BRIEF DESCRIPTION OF THE DRAWINGS

FIG. 1 is a sectional view illustrating a configuration of a substantial part of a semiconductor device according to First Embodiment;

FIG. 2 is a view illustrating an example of a sectional TEM image of an ordered region in the semiconductor device;

FIG. 3A is an image in which the ordered region in FIG. 2 is enlarged;

FIG. 3B is a view showing intensity distribution of a Fourier-transformed image of FIG. 3A;

FIG. 4A is a graph showing measured values indicating the relationship between electron densities and depths from the interface between an interlayer insulating film and an oxide semiconductor layer, in the oxide semiconductor layer shown in FIG. 2;

FIG. 4B is a graph showing results of simulating the relationship between the electron density and the depth;

FIG. 5 is a TEM image of an oxide semiconductor layer according to a comparative example;

FIG. 6 is a view showing intensity distribution of a Fourier-transformed image of the oxide semiconductor layer shown in FIG. 5;

FIG. 7 is a graph showing the relationship between electron densities and depths from the interface between an interlayer insulating film and an oxide semiconductor layer, in the oxide semiconductor layer shown in FIG. 5;

FIG. 8 is a sectional view illustrating a configuration of a semiconductor device according to Second Embodiment;

FIG. 9 is a plan view illustrating a configuration of a second transistor; and

FIG. 10 is a sectional view illustrating a configuration of a semiconductor device according to Third Embodiment.

### DETAILED DESCRIPTION

Hereinafter, some embodiments will be described using the accompanying drawings. The same or like components illustrated in each drawing are denoted by like reference numerals, and the duplicative descriptions will be appropriately omitted.

### First Embodiment

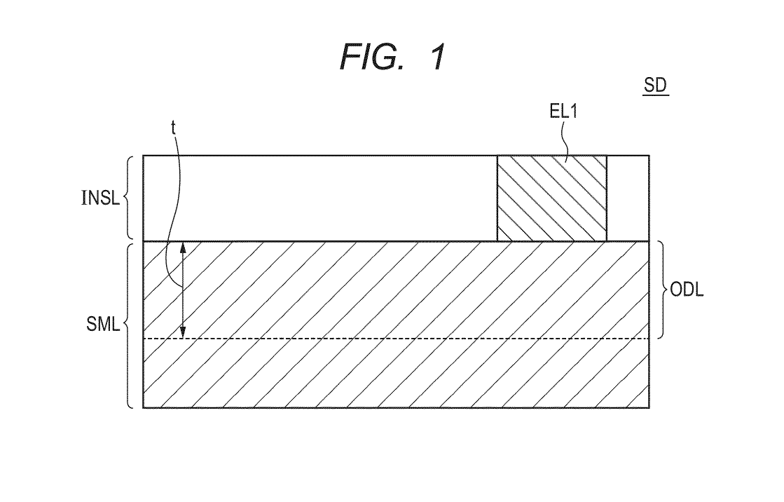

FIG. 1 is a sectional view illustrating a configuration of a substantial part of a semiconductor device SD according to First Embodiment. The semiconductor device SD according to the present embodiment includes an oxide semiconductor layer SML and an electrode EL1. The electrode EL1 is coupled to one surface of the oxide semiconductor layer SML. A portion of the oxide semiconductor layer SML, spanning from the one surface to a depth of t, becomes an ordered layer ODL. The ordered layer ODL is an area including a plurality of ordered regions in each of which the arrangement of atoms is compliant with a specific rule. The maximum width of the ordered region in a section in a direction perpendicular to the one surface is 2 nm or less. In a section in a direction intersecting with the one surface (e.g., a direction perpendicular thereto), the ratio of the ordered region is, for example, 50% or more. The ordered region is, for example, part of the crystal lattice of a compound semiconductor that forms the oxide semiconductor layer SML. Detailed description will be made hereinafter.

The oxide semiconductor layer SML includes, for example, at least one of In, Sn, and Zn. When the oxide semiconductor layer SML is an n-type, the oxide semiconductor layer SML is formed, for example, of InₓGa_{y}Zn_{z}O₄ (0≦x, y, z≦1) or SnOₓ (0≦x≦1). When the oxide semiconductor layer SML is p-type, the oxide semiconductor layer SML is formed, for example, of SnO. Herein, the composition of the aforementioned compound semiconductor may be shifted slightly. The oxide semiconductor layer SML is used as a layer in a semiconductor element, in which a carrier (e.g., an electron or a hole) moves. The oxide semiconductor layer SML is, for example, a channel layer of a transistor. The thickness of the oxide semiconductor layer SML is, for example, 1 nm or more and 100 nm or less.

The width of the ordered region in the oxide semiconductor layer SML, for example, the equivalent circle diameter of the ordered region in a section, is smaller than the length of the longest side of a unit cell in the oxide semiconductor that forms the oxide semiconductor layer SML. In other words, the ordered region that forms the oxide semiconductor layer SML is formed by part (e.g., 30% to 80%) of the crystal lattices of an oxide semiconductor. The ordered region is in a state different from an amorphous state.

The oxide semiconductor layer SML is formed, for example, over an insulating foundation layer by using a vapor-phase growth method, such as a plasma CVD method. The aforementioned crystal state of the oxide semiconductor layer SML can be attained by controlling a film formation condition, for example, oxygen partial pressure.

The electrode EL1 is a via (or a contact) embedded, for example, in an interlayer insulating film INSL, and is formed of a metal, such as Al, W, Cu, or the like. The interlayer insulating film INSL is formed, for example, of silicon oxide.

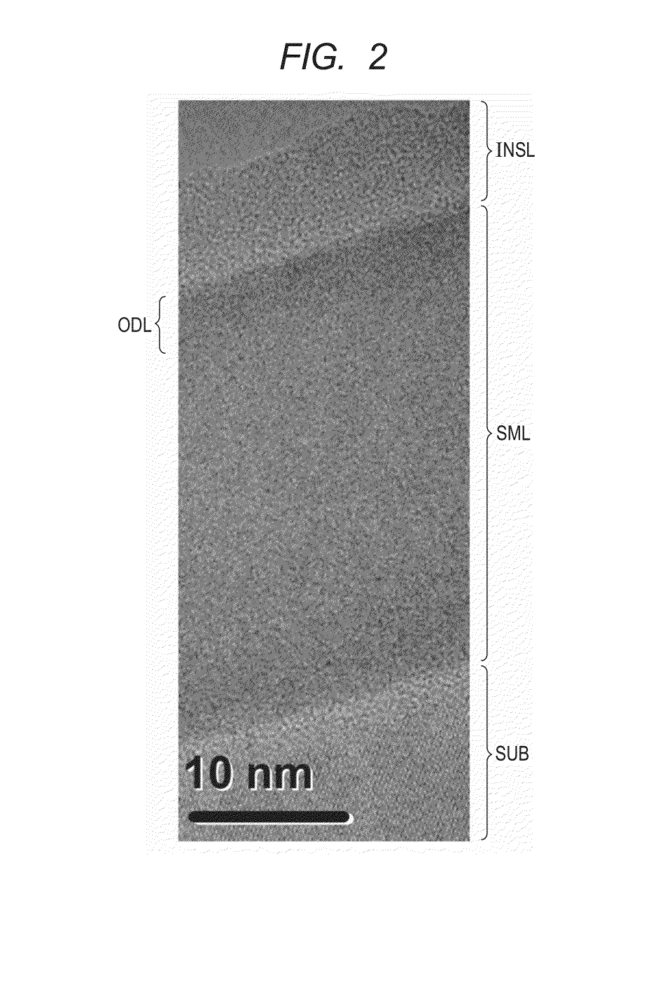

FIG. 2 illustrates an example of a sectional TEM image of the ordered layer ODL in the semiconductor device SD. In this example, the oxide semiconductor layer SML is formed of InₓGa_{y}Zn_{z}O₄ and formed over a substrate SUB, for example, a silicon substrate. The surface layer of the oxide semiconductor layer SML is made to be the ordered layer ODL.

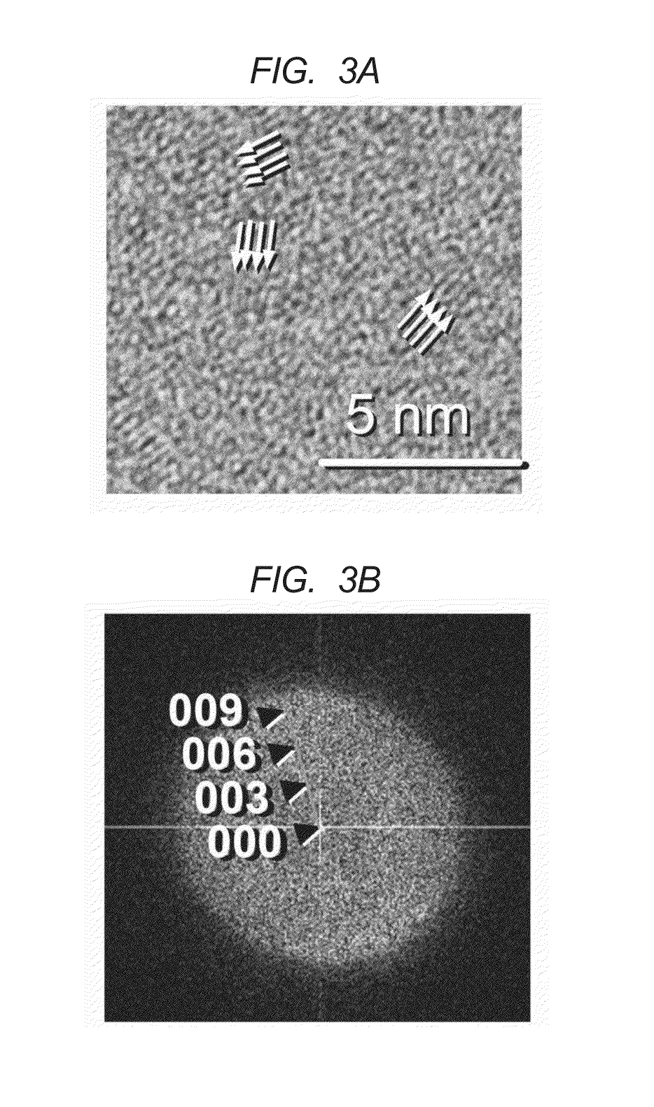

FIG. 3A is an image in which the ordered layer ODL in FIG. 2 is enlarged. FIG. 3B is a view showing intensity distribution of a Fourier-transformed image of FIG. 3A. As shown in FIG. 3A, in a portion of the oxide semiconductor layer SML, which is located in the ordered layer ODL, atoms are arrayed along a specific order (e.g., along part of the crystal lattice of InₓGa_{y}Zn_{z}O₄) in an area within a depth of 2 nm (ordered region). And as shown in FIG. 3B, no diffraction peak is present in the intensity distribution of the Fourier-transformed image of the TEM image of the ordered layer ODL. This shows that the ordered layer ODL is not a microcrystal layer, and in other words, even if an ordered region is included in the ordered layer ODL, the ordered region is smaller than the crystal lattice. Further, the intensity distribution of this Fourier-transformed image is different from a phase contrast transfer function of a lens system included in a TEM used to acquire the TEM image. This shows that the ordered layer ODL is not an amorphous layer and includes an ordered region.

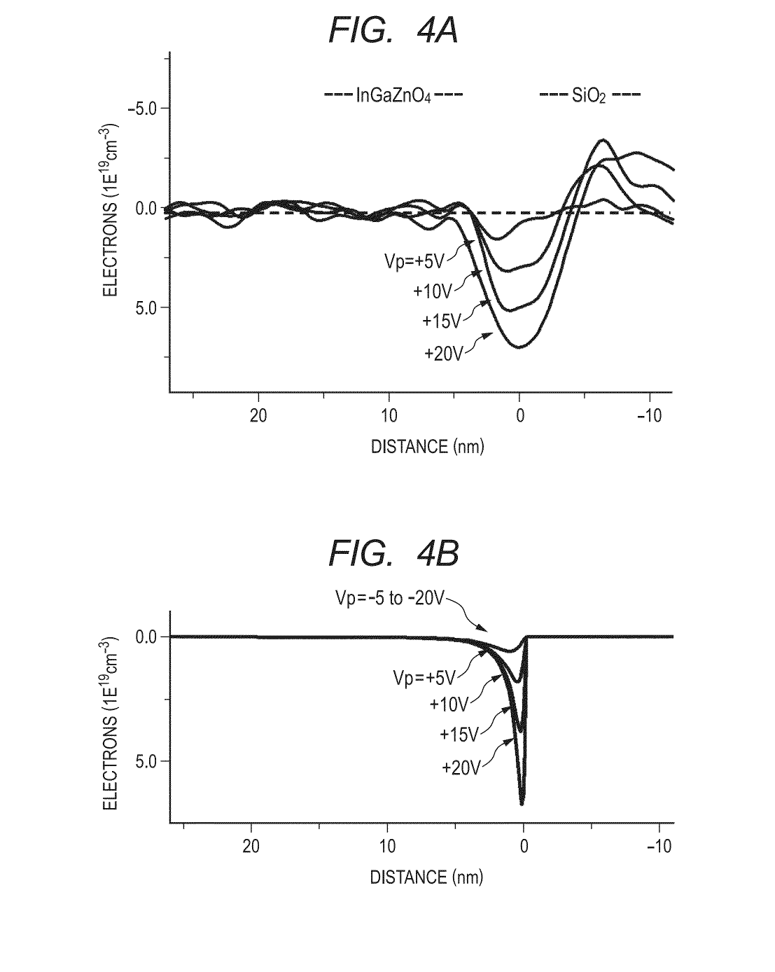

Hereinafter, advantages of the present embodiment will be described with reference to FIGS. 4A to 7.

Each of FIGS. 4A and 4B is a graph showing the relationship between electron densities and depths from the interface between the interlayer insulating film INSL and the oxide semiconductor layer SML, in the oxide semiconductor layer SML shown in FIG. 2. FIG. 4A shows measured values, while FIG. 4B shows results of simulating the relationship. These graphs show that electron densities in the surface layer of the oxide semiconductor layer SML, i.e., electron densities in an area of the oxide semiconductor layer SML that is near to the interface between the interlayer insulating film INSL and the oxide semiconductor layer SML (e.g., an area within a depth of 5 nm), are very high. Herein, the peak of the electron densities in FIG. 4A has a shape somehow broader than that of the simulation results in FIG. 4B; however, it is due to the resolution of a measurement instrument. The fact that the peak has a broader shape due to the resolution of a measurement instrument is understood from the fact that, in FIG. 4A, electron densities in the lower layer formed of SiO₂, which is an insulator, are also high.

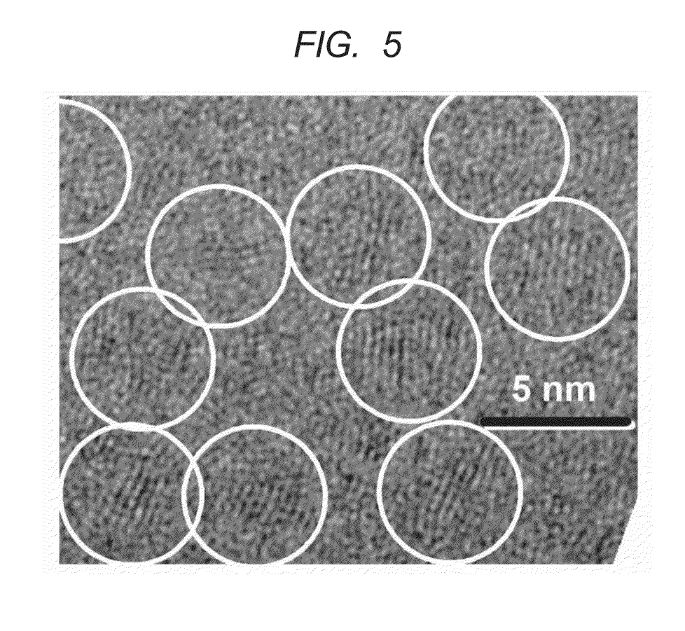

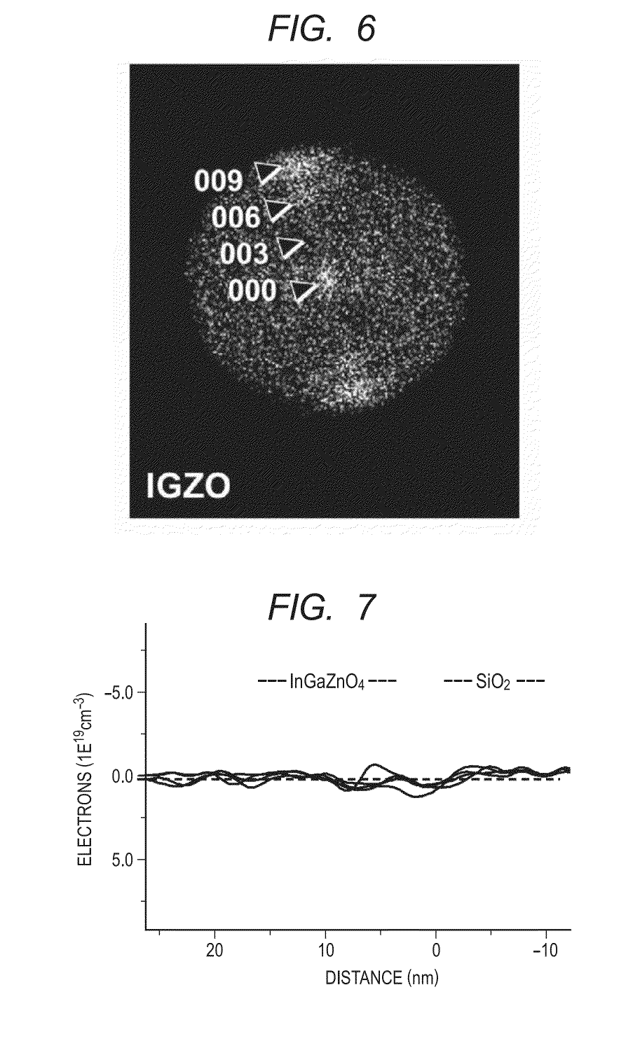

FIGS. 5 to 7 are presented for describing an oxide semiconductor layer SML according to a comparative example. In detail, FIG. 5 is a TEM image of the oxide semiconductor layer SML according to the comparative example, and FIG. 6 is a view showing intensity distribution of a Fourier-transformed image of the oxide semiconductor layer SML shown in FIG. 5. FIG. 7 is a graph showing measured values indicating the relationship between electron densities and depths from the interface between an interlayer insulating film INSL and the oxide semiconductor layer SML, in the oxide semiconductor layer SML shown in FIG. 5. FIGS. 5 to 7 correspond to FIGS. 2, 3B, and 4, respectively.

The size of a grain in the oxide semiconductor layer SML shown in FIG. 5 is approximately 5 nm. That is, the oxide semiconductor layer SML in FIG. 5 is a microcrystal layer. Accordingly, a diffraction peak is present in the intensity distribution of the Fourier-transformed image, as shown in FIG. 6. When FIG. 7 and FIG. 4A are compared with each other, it is known that the electron density in the surface layer of the oxide semiconductor layer SML according to the present embodiment is higher than that in the surface layer of the oxide semiconductor layer SML (i.e., a microcrystal layer) according to the comparative example.

Accordingly, a semiconductor element (e.g., transistor), which has been manufactured by using the oxide semiconductor layer SML according to the present embodiment, has a higher performance. Further, a variation in the film quality of the oxide semiconductor layer SML can be suppressed, because the ordered region in the oxide semiconductor layer SML is fine.

### Second Embodiment

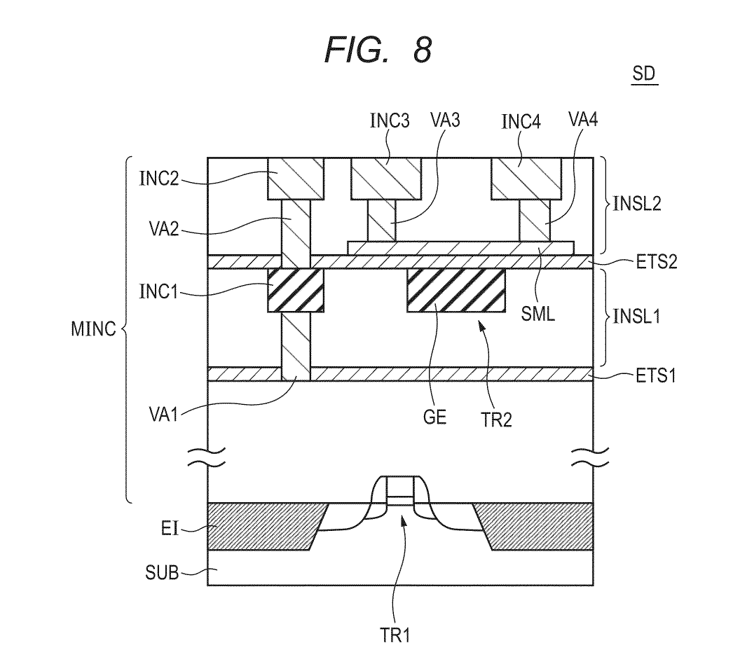

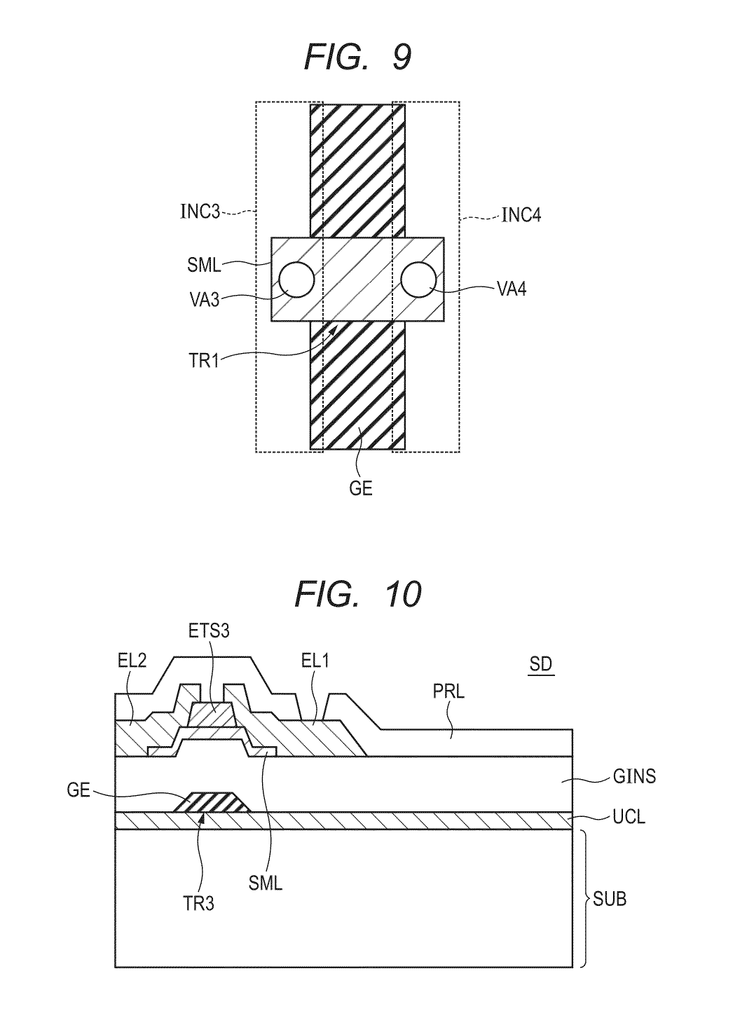

FIG. 8 is a sectional view illustrating a configuration of a semiconductor device SD according to Second Embodiment. FIG. 9 is a plan view illustrating a configuration of a second transistor TR2 included in the semiconductor device SD. The semiconductor device SD according to the present embodiment includes a multilayer interconnection layer MINC over a substrate SUB. The substrate SUB is, for example, a silicon substrate. An element isolation film EI and a first transistor TR1 are formed in the substrate SUB. The first transistor TR1 forms, for example, a logic circuit. The second transistor TR2 is formed in the multilayer interconnection layer MINC.

In detail, the multilayer interconnection layer MINC includes an etching stopper film ETS1. An interconnection layer having at least one layer is formed under the etching stopper film ETS1. An interlayer insulating film INSL1 is formed over the etching stopper film ETS1. A via VA1 and interconnection INC1 are embedded in the interlayer insulating film INSL1. The via VA1 and the interconnection INC1 may be formed by a single damascene method or a dual damascene method. The via VA1 and the interconnection INC1 are formed, for example, of copper.

An etching stopper film ETS2 and an interlayer insulating film INSL2 are formed in this order over the interlayer insulating film INSL1. The etching stopper film ETS2 is, for example, an SiN film or an SiCN film. A via VA2 and interconnection INC2 are embedded in the interlayer insulating film INSL2. The via VA2 couples the interconnection INC1 and the interconnection INC2 together. The via VA2 and the interconnection INC2 may be formed by a single damascene method or a dual damascene method. The via VA2 and the interconnection INC2 are formed, for example, of copper.

The second transistor TR2 of a bottom gate type is formed in the interlayer insulating films INSL1 and INSL2. A gate electrode GE of the second transistor TR2 is formed in the same step as that for the interconnection INC1, and is embedded in the surface layer of the interlayer insulating film INSL1. The gate electrode GE is formed, for example, of copper.

A gate insulating film of the second transistor TR2 is located in the same layer as the etching stopper film ETS2. In the example illustrated in this view, the gate insulating film of the second transistor TR2 is the etching stopper film ETS2. However, the gate insulating film of the second transistor TR2 may be formed of a material different from that of the etching stopper film ETS2.

An oxide semiconductor layer SML is formed over the etching stopper film ETS2. The oxide semiconductor layer SML has the same configuration as that of the oxide semiconductor layer SML described in First Embodiment, and a channel of the second transistor TR2 is formed. An ordered layer ODL is formed in a surface of the oxide semiconductor layer SML, the surface being opposite to the etching stopper film ETS2, and a via VA3 (electrode) and a via VA4 (electrode) are coupled to the surface. The via VA3 and the via VA4 are a source electrode and a drain electrode of the second transistor TR2. A source region and a drain region may be formed in the oxide semiconductor layer SML. The width of an area between the via VA3 and the via VA4 is, for example, 0.1 μm or more and 10 μm or less.

The vias VA3 and VA4 are formed in the same step as that for the via VA2. Interconnection INC3 and interconnection INC4 are embedded in the interlayer insulating film INSL2. The interconnection INC3 is coupled to the oxide semiconductor layer SML through the via VA3, while the interconnection INC4 coupled thereto through the via VA4. The Interconnection INC3 and the interconnection INC4 are formed, for example, of copper, and formed in the same step as that for the interconnection INC2.

Hereinafter, a method of manufacturing the semiconductor device SD according to the present embodiment will be described. First, the element isolation film EI is formed in the substrate SUB. Thereby, an element formation region is isolated. The element isolation film EI is formed, for example, by using an STI method, but may be formed by using a LOCOS method. Subsequently, the gate insulating film and the gate electrode are formed in the substrate SUB located in the element formation region. The gate insulating film may be a silicon oxide film or a high dielectric constant film (e.g., a hafnium silicate film) having a dielectric constant higher than that of a silicon oxide film. When the gate insulating film is a silicon oxide film, the gate electrode is formed by a polysilicon film. Alternatively, when the gate insulating film is a high dielectric constant film, the gate electrode is formed by a laminated film of a metal film (e.g., TiN film) and a polysilicon film. When the gate electrode is formed of polysilicon, a polysilicon resistance may be formed over the element isolation film in the step of forming the gate electrode.

Subsequently, an extension region for a source and a drain is formed in the substrate SUB located in the element formation region. Subsequently, a sidewall is formed in a side wall of the gate electrode. Subsequently, an impurity region that will serve as the source and the drain is formed in the substrate SUB located in the element formation region. Thus, the first transistor TR1 is formed over the substrate SUB.

Of the multilayer interconnection layer MINCS, a layer under the etching stopper film ETS1 is then formed over the substrate SUB, the element isolation film EI, and the first transistor TR1. Subsequently, the etching stopper film ETS1, the interlayer insulating film INSL1, the via VA1, the interconnection INC1, and the gate electrode GE are formed.

Subsequently, the etching stopper film ETS2 is formed over the insulating layer INSL1. Subsequently, the oxide semiconductor layer SML is formed over the etching stopper film ETS2 by using, for example, a plasma CVD method. The temperature at which the oxide semiconductor layer SML is formed is, for example, 400° C. or lower. Accordingly, the multilayer interconnection layer MINC and the first transistor TR1 can be suppressed from being damaged when the oxide semiconductor layer SML is formed. Subsequently, a mask pattern is formed over the oxide semiconductor layer SML such that, of the oxide semiconductor layer SML, an unnecessary portion is removed by performing etching with the use of the mask pattern as a mask.

Subsequently, the interlayer insulating film INSL2, the vias VA2, VA3, and VA4, the interconnection INC2, the interconnection INC3, and the interconnection INC4 are formed over the etching stopper film ETS2 and the oxide semiconductor layer SML.

According to the present embodiment, the second transistor TR2, a switching element, can be formed in the multilayer interconnection layer MINC. The second transistor TR2 is coupled to any one of the first transistors TR1. Accordingly, the function of the semiconductor device SD can be changed drastically without a change in the layout of the first transistor TR1 formed in the substrate SUB.

Further, the first transistor TR1 and the second transistor TR2 can be superimposed together, in plan view. Accordingly, the integration rate of the semiconductor device SD can be improved.

The second transistor TR2 is formed by using the oxide semiconductor layer SML. As described in First Embodiment, the electron density in the surface layer of the oxide semiconductor layer SML, that is, the electron density in the layer to which the vias VA 3 and VA4 are coupled is high. Accordingly, the property of the second transistor TR2 can be enhanced.

In the present embodiment, the ordered layer ODL in the oxide semiconductor layer SML only has to be formed at least in an area between the vias VA3 and VA4.

### Third Embodiment

FIG. 10 is a sectional view illustrating a configuration of a semiconductor device SD according to Third Embodiment. The semiconductor device SD according to the present embodiment includes a third transistor TR3 that is a TFT (Thin Film Transistor). The third transistor TR3 is a transistor of a bottom gate type, and has an oxide semiconductor layer SML as a channel layer.

In detail, a substrate SUB is made, for example, of a resin or glass in the present embodiment. An undercoat layer UCL is formed over the substrate SUB. The undercoat layer UCL is formed, for example, of silicon nitride, aluminum nitride, or aluminum oxide.

A gate electrode GE is formed over the undercoat layer UCL. The gate electrode GE includes, as a major component, at least one component selected from the group consisting, for example, of molybdenum, titanium, chromium, tantalum, tungsten, aluminum, and copper. For example, the gate electrode GE is formed of a single metal or alloy. The gate electrode GE may have a single layer structure or a laminated structure.

A gate insulating film GINS is formed over the gate electrode GE and the undercoat layer UCL. The gate insulating film GINS is formed, for example, of silicon oxide.

The oxide semiconductor layer SML is formed over an area of the gate insulating film GINS, the area being superimposed over the gate electrode GE, in plan view. The configuration of the oxide semiconductor layer SML is the same as that in First Embodiment. The oxide semiconductor layer SML is formed to be larger than the gate electrode GE, in a direction (horizontal direction in FIG. 10) intersecting with the direction in which the gate electrode GE is extended.

An etching stopper film ETS3 is formed over an area of the oxide semiconductor layer SML, the area being superimposed over the gate electrode GE, in plan view. In other words, the oxide semiconductor layer SML is seemingly divided into two regions by the etching stopper film ETS3. An electrode EL1 is formed over one of the two regions of the oxide semiconductor layer SML, while an electrode EL2 is formed over the other thereof. The gate electrodes EL1 and EL2 are source/drain electrodes, each of which includes, as a major component, at least one component selected from the group consisting, for example, of molybdenum, titanium, chromium, tantalum, tungsten, aluminum, and copper. For example, the gate electrode GE is formed of a single metal or alloy.

A protective layer PRL is formed over the etching stopper film ETS and the electrodes EL1 and EL2. The protective layer PRL is, for example, a silicon nitride film. An opening for pulling out the electrodes EL1 and EL2 outside is provided in the protective layer PRL.

According to the present embodiment, the electron density in the oxide semiconductor layer SML is high, because the oxide semiconductor layer SML has the same configuration as that in First Embodiment. Accordingly, the property of the third transistor TR3 can be improved.

In the present embodiment, an ordered layer ODL in the oxide semiconductor layer SML only has to be formed at least in an area between the electrodes EL1 and EL2. The aforementioned advantages can also be obtained in TFTs having other structures.

The invention made by the present inventors has been described above based on preferred embodiments, but the invention should not be limited to the preferred embodiments, and it is needless to say that various modifications may be made to the invention within a range not departing from the gist of the invention.

What is claimed is:

1. A semiconductor device comprising:
an oxide semiconductor layer; and
an electrode coupled to one surface of the oxide semiconductor layer,
wherein the oxide semiconductor layer includes a plurality of ordered regions in each of which the arrangement of atoms is compliant with a specific rule, in an area spanning at least from the one surface to a depth of 2 nm, and a maximum width of the ordered region in a section in a direction perpendicular to the one surface is 2 nm or less.

2. The semiconductor device according to claim 1,
wherein a width of the ordered region is smaller than the length of the longest side of a unit cell in an oxide semiconductor that forms the oxide semiconductor layer.

3. The semiconductor device according to claim 1,
wherein no diffraction peak is present in intensity distribution of a Fourier-transformed image of a TEM (Transmission Electron Microscope) image of the ordered region, and the intensity distribution is different from a phase contrast transfer function of a lens system included in a TEM used to acquire the TEM image.

4. The semiconductor device according to claim 1,
wherein the oxide semiconductor includes at least one of In, Sn, and the Zn.

5. The semiconductor device according to claim 4,
wherein the oxide semiconductor is InₓGa_{y}Zn_{z}O₄ (0≦x, y, z≦1) or SnOₓ (0<x≦1).

6. The semiconductor device according to claim 1 comprising two of the electrodes that are spaced apart from each other,
wherein the oxide semiconductor layer and the two electrodes are part of a transistor.

7. A semiconductor device comprising:
an oxide semiconductor layer; and
an electrode provided on one surface side of the oxide semiconductor layer,
wherein no diffraction peak is present in intensity distribution of a Fourier-transformed image of a TEM (Transmission Electron Microscope) image of an area of the oxide semiconductor layer, the area spanning from at least the one surface to a depth of 2 nm, and the intensity distribution is different from a phase contrast transfer function of a lens system included in a TEM used to acquire the TEM image.
